(19) United States
(12) Patent Application Publication
(10) Pub. No.: US 2012/0118627 A1
(43) Pub. Date: May 17, 2012

(54) ELECTROMAGNETIC SHIELDING ARTICLE AND METHOD FOR MANUFACTURING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CHUANG MA, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (TW)

(21) Appl. No.: 13/032,724

(22) Filed: Feb. 23, 2011

(30) Foreign Application Priority Data
Nov. 11, 2010 (CN) 201010539947.1

(51) Int. Cl. H05K 9/00; C23C 14/14; C23C 14/58; C23C 14/35

(52) U.S. Cl. 174/388; 204/192.15; 204/192.3

(57) ABSTRACT

An electromagnetic shielding article includes a plastic substrate; an aluminum layer deposited on the plastic substrate; an electromagnetic shielding layer deposited on the aluminum layer; and a protection layer deposited on the electromagnetic shielding layer.

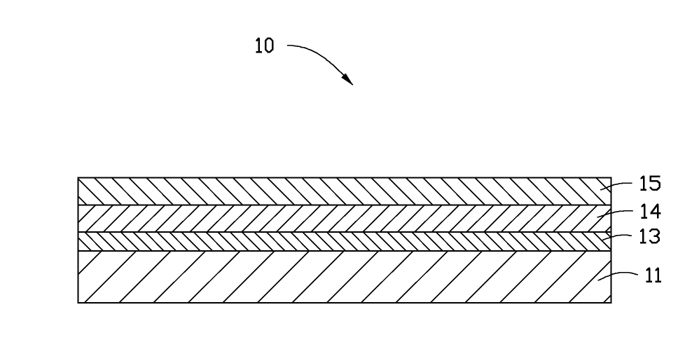

### CROSS-REFERENCE TO RELATED APPLICATIONS

The present application is related to co-pending U.S. patent applications (Attorney Docket No. US34917, US35618), each entitled “ELECTROMAGNETIC SHIELDING ARTICLE AND METHOD FOR MANUFACTURING SAME”, by Zhang et al. These applications have the same assignee as the present application and have been concurrently filed herewith. The above-identified applications are incorporated herein by reference.

### BACKGROUND

1. Technical Field

The exemplary disclosure generally relates to electromagnetic shielding articles and methods for manufacturing the electromagnetic shielding articles.

2. Description of Related Art

The operation of portable electronic devices such as mobile telephone, televisions, radios, computers, medical instruments, business machines, communications equipment, and the like generates electromagnetic radiation within the electronic circuitry of the equipment, and is termed “electromagnetic interference” or “EMI”. EMI is known to interfere with the operation of other nearby electronic devices.

To attenuate EMI effects, shielding can having the capability of absorbing and/or reflecting EMI energy may be employed to confine the EMI energy within a source device, and to insulate that device or other “target” devices from other source devices. A typical shielding may comprise a plastic substrate and an electrically-conductive layer coated on the plastic substrate. However, it is difficult to coat an electrically-conductive layer on a plastic substrate.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary electromagnetic shielding article and method for manufacturing the electromagnetic shielding article. Moreover, in the drawings like reference numerals designate corresponding parts throughout the several views. Wherever possible, the same reference numbers are used throughout the drawings to refer to the same or like elements of an exemplary embodiment.

The FIGURE is a cross-sectional view of an exemplary embodiment of an electromagnetic shielding article.

### DETAILED DESCRIPTION

Referring to FIGURE, an exemplary embodiment of an electromagnetic shielding article 10 includes a plastic substrate 11, an aluminum layer 13 deposited on the plastic substrate 11 by magnetron sputtering process, an electromagnetic shielding layer 14 deposited on the aluminum layer 13 by magnetron sputtering process and a protection layer 15 deposited on the electromagnetic shielding layer 14 by magnetron sputtering process.

The aluminum layer 13 has a thickness between about 30 nanometers and about 150 nanometers. The electromagnetic shielding layer 14 is made of metal, such as copper, silver. The electromagnetic shielding layer 14 has a thickness between about 100 nanometers and about 400 nanometers. The copper and the silver have a low resistivity, so the electromagnetic shielding layer 14 made from the copper and the silver provides affective electromagnetic shielding. The protection layer 15 improves the corrosion resistance of the electromagnetic shielding article 10. In this exemplary embodiment, the protection layer 15 is a stainless steel layer and has a thickness between about 50 nanometers and about 300 nanometers. The protection layer 15 can improve the corrosion resistance of the electromagnetic shielding article 10, to prevent losing electromagnetic shielding functionality.

A method for manufacturing the electromagnetic shielding article 10 may include at least the following steps.

A plastic substrate 11 is provided. The plastic substrate 11 may be made of plastic, such as polyvinyl chloride, polyethylene, polystyrene, polypropylene, polycarbonate, cellulose nitrate, phenol-formaldehyde, polyurethane, epoxide resin, by injection molding process.

A vacuum coating machine (not shown) is provided. The vacuum coating machine may include a plasma cleaning chamber, a first metal spraying chamber, a second metal spraying chamber, a third metal spraying chamber, a transmission device and a rotating bracket mounted on the transmission device.

The plastic substrate 11 is cleaned by argon plasma cleaning. The plastic substrate 11 is retained on the rotating bracket, and then is moved into the plasma cleaning chamber. The vacuum level inside the plasma cleaning chamber is set to 5.0×10-3 Pa, pure argon is floated into the plasma cleaning chamber at a flux of about 100 Standard Cubic Centimeters per Minute (sccm) to 350 sccm, in this exemplary embodiment is at about 270 sccm. An ion source in the plasma cleaning chamber is started at a power of about 700 W to about 1000 W for about 0.5 minutes to about 10 minutes, to produce argon ions. In this exemplary embodiment, the ion source in the plasma cleaning chamber is started at a power of about 900 W for about 1 minute. The argon ions are then emitted on the plastic substrate 11. So the plastic substrate 11 is washed by argon plasma, to remove the grease or dirt.

A aluminum layer 13 is deposited on the plastic substrate 11 by magnetron sputtering process. The substrate 11 is moved into the first metal spraying chamber by the transmission device, and in this exemplary embodiment, the speed of the transmission device is about 0.5 meter per second (m/s) to 2.0 m/s, preferably is about 1.3 m/s. The argon is floated into the first metal spraying chamber at a flux of about 100 sccm to 300 sccm, and in this exemplary embodiment is at about 180 sccm. The temperature inside the first metal spraying chamber is heated to about 50° C. to about 150° C., and in this exemplary embodiment is at about 80° C. A aluminum target in the first metal spraying chamber is evaporated at a power of about 300 W to about 800 W, to deposit the aluminum layer 13 on the plastic substrate 11. In this exemplary embodiment, the aluminum target is evaporated at a power of about 500 W.

An electromagnetic shielding layer 14 is deposited on the aluminum layer 13 by magnetron sputtering process. The substrate 11 is moved into to the second metal spraying chamber by the transmission device, and in this exemplary embodiment, the speed of the transmission device is about 0.5 m/s to 2.0 m/s, preferably is about 1.3 m/s. The temperature inside the second metal spraying chamber is set to 50˜150° C. Argon is floated into the second metal spraying chamber at a flux of about 100 sccm to about 300 sccm. A copper or silver target in the second metal spraying chamber is evaporated at a power from 500 W to 1500 W, to deposit the electromagnetic shielding layer 14 on the aluminum layer 13. In this exemplary embodiment, the copper or silver target is evaporated at a power of about 1000 W. The copper and the silver has a low resistivity, so the electromagnetic shielding layer 14 made from the copper and the silver provides affective electromagnetic shielding.

A protection layer 15 is deposited on the electromagnetic shielding layer 14 by magnetron sputtering process. The substrate 11 is moved into the third metal spraying chamber by the transmission device, and in this exemplary embodiment, the speed of the transmission device is about 0.5 m/s to 2.0 m/s, preferably is about 1.3 m/s. The temperature inside the third metal spraying chamber is set to 50˜150° C. Argon is floated into the third metal spraying chamber at a flux of about 75 sccm to about 150 sccm. A stainless steel target in the third metal spraying chamber is evaporated at a power from 1 kW to 10 kW, to deposit the protection layer 15 on the electromagnetic shielding layer 14. In this exemplary embodiment, the stainless steel target is evaporated at a power about 1000 W.

When the electromagnetic shielding article 10 is tested by cross hatch test process, the classification of cross hatch test results is 0 B, i.e., there is no peeling off in the electromagnetic shielding article 10.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electromagnetic shielding article, comprising:
a plastic substrate;
an aluminum layer deposited on the plastic substrate;
an electromagnetic shielding layer deposited on the aluminum layer; and
a protection layer deposited on the electromagnetic shielding layer.

2. The electromagnetic shielding article as claimed in claim 1, wherein the aluminum layer is deposited on the plastic substrate by magnetron sputtering process and has a thickness between about 30 nanometers and about 150 nanometers.

3. The electromagnetic shielding article as claimed in claim 1, wherein the electromagnetic shielding layer is made of metal.

4. The electromagnetic shielding article as claimed in claim 3, wherein the metal is copper or silver.

5. The electromagnetic shielding article as claimed in claim 1, wherein the electromagnetic shielding layer has a thickness between about 100 nanometers and about 400 nanometers.

6. The electromagnetic shielding article as claimed in claim 1, wherein the protection layer is a stainless steel layer.

7. The electromagnetic shielding article as claimed in claim 6, wherein the protection layer has a thickness between about 50 nanometers and about 300 nanometers.

8. A method for manufacturing an electromagnetic shielding article comprising steps of:
providing a plastic substrate;
depositing a aluminum layer on the plastic substrate;
depositing an electromagnetic shielding layer on the aluminum layer; and
depositing a protection layer on the electromagnetic shielding layer.

9. The method of claim 8 wherein the aluminum layer is deposited by magnetron sputtering process.

10. The method of claim 9, wherein the plastic substrate is made of plastic.

11. The method of claim 10, wherein the plastic is polyvinyl chloride, polyethylene, polystyrene, polypropylene, polycarbonate, cellulose nitrate, phenol-formaldehyde, polyurethane, or epoxide resin.

12. The method of claim 9, wherein during depositing the aluminum layer on the plastic substrate, the plastic substrate is retained in a first metal spraying chamber, argon is floated into the first metal spraying chamber at a flux of about 100 sccm to 300 sccm; the temperature inside the first metal spraying chamber is heated to 50 to 150° C.; a aluminum target in the first metal spraying chamber is evaporated at a power of about 300 W to about 800 W, to deposit the aluminum layer on the plastic substrate.

13. The method of claim 9, wherein during depositing the electromagnetic shielding layer on the aluminum layer, the plastic substrate is retained in a second metal spraying chamber, the temperature inside the second metal spraying chamber is set to 50˜150° C.; argon is floated into the second metal spraying chamber at a flux of about 100 sccm to about 300 sccm; a copper or silver target in the second metal spraying chamber is evaporated at a power from 500 W to 1500 W, to deposit the electromagnetic shielding layer on the aluminum layer.

14. The method of claim 9, wherein during depositing the protection layer on the electromagnetic shielding layer, the plastic substrate is retained in a third metal spraying chamber, the temperature inside the third metal spraying chamber is set to 50˜150° C.; argon is floated into the third metal spraying chamber at a flux of about 75 sccm to about 150 sccm; a stainless steel target in the third metal spraying chamber is evaporated at a power from 1 kW to 10 kW, to deposit the protection layer on the electromagnetic shielding layer.

15. The method of claim 9, further including a step of cleaning the plastic substrate by argon plasma cleaning between providing a plastic substrate and depositing the aluminum layer on the plastic substrate.

16. The method of claim 15 wherein during cleaning the plastic substrate, the plastic substrate is retained in a plasma cleaning chamber, the vacuum level inside the plasma cleaning chamber is set to 5.0×10-3 Pa, pure argon is floated into the plasma cleaning chamber at a flux of about 100 sccm to 350 sccm, and an ion source in the plasma cleaning chamber is started at a power of about 700 W to about 1000 W for about 0.5 minutes to about 10 minutes, to clean the plastic substrate.
